(19) United States
(12) Patent Application Publication
(10) Pub. No.: US 2003/0167631 A1
(43) Pub. Date: Sep. 11, 2003

(54) MOUNTING ASSEMBLY FOR PREMISES AUTOMATION SYSTEM COMPONENTS

(76) Inventor: Peter D. Hallenbeck, Efland, NC (US)

Correspondence Address: MOORE & VAN ALLEN, PLLC, 2200 W MAIN STREET, SUITE 800, DURHAM, NC, 27705, US

(21) Appl. No.: 10/248,926

(22) Filed: Mar. 3, 2003

Related U.S. Application Data
(60) Provisional application No. 60/361,675, filed on Mar. 5, 2002.

(51) Int. Cl. H05K 3/30

(52) U.S. Cl. 29/835

(57) ABSTRACT

A method and assembly for terminating premises automation equipment wiring by mounting premises automation components in readily available holders. A mount for premises automation system components is provided using a punchdown block holder. Opposing tabs of the punchdown block holder bias a printed circuit board (PCB) or a mechanical adapter plate against the holder's top surface. The PCB or mechanical adapter are sized and shaped so that the PCB or adapter snaps in between the tabs and is held against the block holder. An additional PCB may be mounted on top of the first PCB or adapter using coaxial holes and fasteners. The planimetric shape of the first PCB or adapter may vary so long as it snuggly fits in the punchdown block holder, and the second PCB may have the same planimetric shape as or vary from that of the first PCB or adapter.

### CROSS REFERENCE TO RELATED APPLICATIONS

This application claims priority from co-pending provisional patent application serial No. 60/361,675, filed Mar. 5, 2002, by the inventor hereof, the entire disclosure of which is incorporated herein by reference.

### BACKGROUND OF INVENTION

Premises automation systems require that a large number of electrical wiring connections be made between a central processing control unit having various interface circuits and various components such as sensors, switches, relays, and other devices. These components may either be near the central unit or distributed throughout the premises.

In some systems, the wiring throughout the premises may be terminated on insulation displacement punchdown blocks, such as a 66 block, a long-used standard electrical terminal device of the telephone industry. Then additional punchdown blocks connect to electronic components, for example, premises automation equipment or telephone equipment. Jumpers may then be punched to provide an electrical connection between the punched-down premises wiring and the control equipment. In some cases, an installer may choose to punchdown the wires directly onto the control equipment. This may reduce initial installation cost, but may lead to more difficult work and higher expense in the future, for example, when the central equipment is replaced, if the new equipment does not have the exact same connections and pinouts as the equipment it replaces.

In a conventional premises automation system installation, an area of wall space may be dedicated to a punchdown area where all the punchdown blocks are located. Due to the large number of wires involved, the punchdown blocks (such as the 66 block) are often snapped into frames called “punchdown block holders”, commonly made of plastic (such as an 89B or 89D bracket). The holders help in the management of the wires, hiding wires that are terminated in the blocks behind the blocks, with jumpers on the sides of the blocks. Holders also raise the surface of the block away from the wiring, making access to the blocks easier and “cleaner”. A standard arrangement for telephone wiring in premises is to have a punchdown area, with one side of the area having several punchdown blocks with building wiring permanently punched down, and the other side of the area having punchdown blocks that connect to the equipment. Jumpers are then used to connect the permanently installed wiring to the equipment.

Part of the reason this technique has worked in the telephone industry is that the telephone environment is substantially homogenous, with telephone circuits being pairs. A 50 wire jack/plug combination is frequently used to connect to a punchdown block, and telephone equipment commonly uses a standard RJ11 plug/jack system. The generic nature of punchdown blocks allows the same style of block to be used for both premises automation and telephone equipment termination.

Conventional premises automation equipment uses termination techniques that employ user connections on a circuit board with the premises automation electronics. The premises wiring comes directly from the building to a housing for the electronics, and commonly connects to screw terminals or “pin and header” terminals that are on the same circuit board as the premises automation electronics. While this has certain economic benefits on initial installation, there are some drawbacks with this approach.

One drawback is that during installation, the circuitry of the premises automation equipment is exposed. Installers who are working with large numbers of wires run the risk of accidental contact with the components on the circuit board causing failures. If the board is powered up, the failures can be dramatic.

Another drawback is that replacing the main circuit board requires unscrewing all wires connecting to the board, changing the board, and re-connecting the wires. This is both a time-consuming and error-prone event. The relatively long time required to replace a board may result in significant expense. Because of the time required to replace a board, a diagnostic technique wherein a new board is installed to identify a problem source is inefficient, and is therefore not used.

An additional drawback is that when the equipment is replaced with a new or different model, the wires are rarely in the correct position to allow for easy termination. If the original installer had the foresight to leave extra wire length available for future maintenance, replacement can be completed without new wiring. But this is often not the case, and even with some slack left in the wires new equipment usually cannot be installed multiple times before new wiring is required. Further aggravating this situation is the fact that buildings are generally expected to last significantly longer than electronic equipment, so it may be expected that electronic equipment will be replaced at least one time in the life of a building, and maybe more.

### SUMMARY OF INVENTION

The present invention provides a method and assembly for terminating premises automation equipment wiring by mounting premises automation components in readily available holders. The method and assembly can include a wide variety of components used in premises automation systems, in unrestricted locations; for example, the components may be mounted near a central unit or may be distributed and mounted throughout the premises. Examples of components of a premises automation system include but are not limited to input/output (I/O) units, voltage regulators, fuses, interconnections, relays, and sensors. The wire termination and mounting assembly of the present invention facilitates modularization of premises automation system components and the separation of components from a central unit of the system.

The invention is implemented through various methods and apparatus. In one embodiment a mount for premises automation system components is provided using a punchdown block holder. Opposing tabs of the punchdown block holder bias an object against the holder's top surface, and the mount comprises a printed circuit board (PCB) sized and shaped so that the PCB snaps in between the tabs and is held against the block holder. An additional PCB may be mounted on top of the first PCB using coaxial holes and fasteners. The “form factor” or planimetric shape of the first PCB may vary so long as it snuggly fits in the punchdown block holder, and the second PCB may have the same form factor as or vary from the form factor of the first PCB. Voids may be placed in the PCB through which the tabs may pass if the form factor of the PCB extends outside the limits of the tabs.

In place of a PCB being mounted to a punchdown block holder, a mount according to the present invention may also comprise a substantially planar mechanical adapter mounted to a holder. The adapter, like the PCB described above, is sized and shaped to snap into the holder between the tabs, where it is held against the holder's top surface. The form factor of the adapter may vary, again so long as the adapter is held between the tabs. Voids may be provided as necessary to allow tabs to extend around and grasp the adapter. One or more PCBs of varying size may then be mounted to the adapter. Enclosures may also be mounted to the adapter, with PCBs mounted to the interior of the enclosures.

In further embodiments of the present invention, a mounting assembly for premises automation system components is provided. The assembly comprises a punchdown block holder and PCBs, adapters, or a combination thereof as discussed above. Similarly, premises automation systems are provided, comprising a central unit, devices that are controlled by the central unit, and separate automation system components that include mounting assemblies in accordance with the present invention. The separate automation system components are electrically interposed between the central unit and the devices.

Methods of mounting premises automation system components are provided. In one method steps comprise providing a punchdown block holder, providing a printed circuit board sized and shaped to be fit into the tabs of the holder, either by its outside limits or through voids, and inserting the printed circuit board between the opposing tabs. In another method a planar adapter is inserted between the opposing tabs of a punchdown block holder. A printed circuit board is provided and mounted to the adapter with fasteners through the corresponding holes.

One further embodiment of a mount for premises automation system components uses standard single-gang wall outlet box and comprises a printed circuit board having a form factor smaller then the interior of the outlet box. Two holes coaxial with the two holes through the rear of the outlet box are provided for mounting the PCB to the interior rear of the outlet box, with fasteners through the coaxial holes.

### BRIEF DESCRIPTION OF DRAWINGS

FIGS. 1 and 2 are provided for reference and are diagrams of exemplary embodiments of premises automation systems in which the present invention may be used.

FIG. 3 is a top plan view of a prior art 66 block.

FIG. 4 is a top plan view of a prior art 89B bracket or holder, used in one embodiment of the present invention and conventionally used to hold the prior art 66 block of FIG. 3.

FIG. 5 is a top plan view of a full-size digital I/O board according to an embodiment of the present invention.

FIG. 6 is a top plan view of a full-size telco/infrared board according to an embodiment of the present invention.

FIG. 7 is a front elevation view of a central unit of a premises automation system according to an embodiment of the present invention.

FIG. 8 is a top plan view of one embodiment of an adapter according to an embodiment of the present invention.

FIG. 9 is a top plan view of a full-size fuse board according to an embodiment of the present invention.

FIG. 10 is a top plan view of a full-size general purpose interconnect board according to an embodiment of the present invention.

FIG. 11 is a top plan view of a single PCB housing according to an embodiment of the present invention.

FIG. 12 is a bottom plan view of a cover for the single PCB housing of FIG. 3.

FIG. 13 is a top plan view of reduced-size voltage regulator boards according to an embodiment of the present invention.

FIG. 14 is a bottom plan view of the bottom of the reduced size adjustable voltage regulator board of FIG. 13.

FIG. 15 is a top plan view of an embodiment of an over-sized PCB or adapter according to an embodiment of the present invention.

FIG. 16 is an exploded perspective view of a mounting assembly according to an embodiment of the present invention.

FIG. 17 is an exploded perspective view of a mounting assembly according to another embodiment of the present invention.

FIG. 18 is a side elevation view of a mounting assembly according to yet another embodiment of the present invention.

### DETAILED DESCRIPTION

Although the description herein describes the present invention with reference to appurtenances of 66 blocks, these specific references are for convenience only. The PCBs and mechanical adapters shown herein are appropriate for use on a conventional 89B holder, but one of ordinary skill in the art could readily alter the PCB and bracket designs to fit other holders, such as an 89D holder. Other similar holders may be used, for example, those for 110 or 25 blocks, also with modification as required to the PCBs and brackets described herein.

Further, the references made herein to the size of the PCBs or “boards” are for convenience of reference only, and are meant to indicate relative size. Boards that generally are sized to fit directly within a holder, as depicted herein an 89B holder, are referred to as “full-size”, while boards that are smaller are referred to as “reduced-size”. Boards larger than full-size are referred to as “over-sized”.

Certain terminology is used herein for convenience only and is not to be taken as a limitation on the invention. For example, words such as “top”, “bottom”, “upper”, “lower”, “left”, “right”, “horizontal”, “vertical”, “upward”, and “downward” merely describe the configuration shown in the Figures. The components may be oriented in any direction and the terminology, therefore, should be understood as encompassing such variations unless specified otherwise. Also, the scope of the invention is not intended to be limited by the materials or dimensions listed herein, but may be carried out using any materials and dimensions that allow the construction and operation of the mounting assembly.

In the Figures herein, unique features receive unique numbers, while features that are the same in more than one drawing receive the same numbers throughout. Where a feature is modified between figures or is modified only by a change in location, a letter may be added or changed after the feature number to distinguish that feature from a similar feature in a previous figure or the same feature in an alternate location.

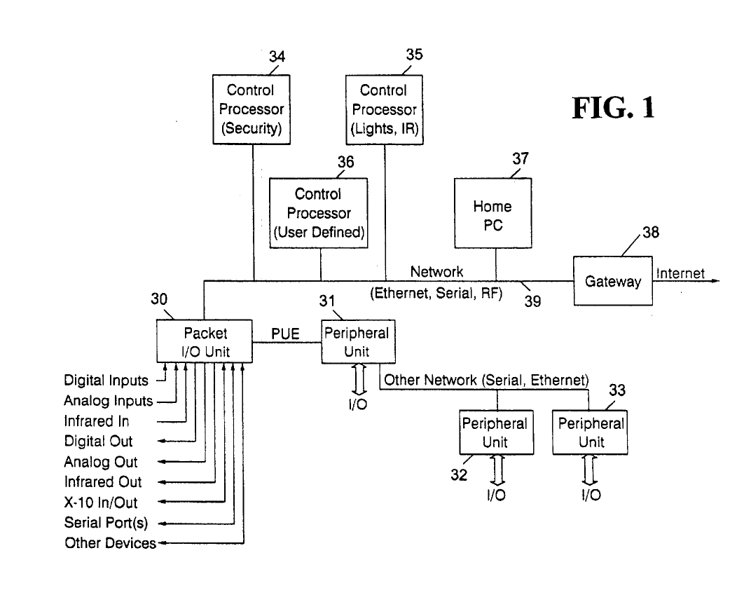

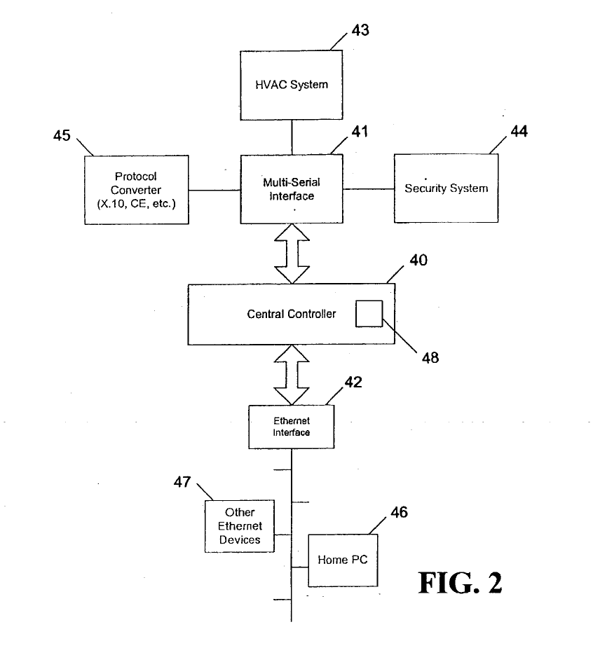

FIGS. 1 and 2 are similar to figures in co-pending U.S. patent application Ser. No. 10/068,157, filed on 6 Feb. 2002 by the same inventor as the present invention. The complete contents of application Ser. No. 10/068,157 are hereby incorporated by reference. FIGS. 1 and 2 show examples of embodiments of premises automation systems in which the present invention may be used. This is in no way intended to be limiting with respect to the use of the present invention, which may also be used in many other premises automation systems. Rather, FIGS. 1 and 2 are included and described in order to give context to and examples of the many components that may be included in various embodiments of the present invention.

FIG. 1 is a network level block diagram. The system of FIG. 1 is fairly large; however, it is shown by way of example only. A system incorporating the invention can be much smaller, even consisting of one I/O unit. This system is comprised of multiple I/O units 30, 31, 32, and 33. An example of the connective topology, used by this example implementation, is packet I/O unit 30 that is connected to a home network including control processor or software program 34 for a security system, control processor or software program 35 which provides lighting and infrared device control, and control processor or software program 36, which is user-defined. A home personal computer, 37, and Internet gateway 38 can also be connected to this network, and are shown in this example. The home network, 39, is often an Ethernet, but can also be a radio frequency (RF) wireless network, a serial network, or any other type of network. The gateway to the Internet, 38 of FIG. 1, is included for facilitating transmission of email or other types of messages or packets over the Internet if a notification of an event needs to be communicated outside the premises.

The additional I/O units are connected to unit 30 via a specialized type of serial port on units 30 and 31, which is called herein a “peripheral unit expansion” (PUE) interface. The PUE electrical interface in the example embodiments shown is similar to an RS-485 port, but may take other forms. Additional units 32 and 33 are connected to unit 31 through a second home network in this example, although they could also be connected through the PUE interface. Units connected through the PUE interface are typically smaller in size, cost, and capability, and are thus referred to as “peripheral I/O units” or simply “peripheral units”, not to be confused with the term “peripheral” as applied to computer peripherals. The serial type PUE interface is slower than many types of network connections, such as Ethernet, but this slower speed is acceptable because of the smaller data bandwidths of the peripheral units.

Each I/O unit has a number of different devices that can connect to its inputs and outputs. Some devices, such as switches and relay contact closures, require little processing. Others, such as analog voltages that represent temperatures, will require a little more processing. And some, such as serial ports and infrared I/O will require still more processing. Some of these inputs and outputs are illustrated in FIG. 1 as connected to packet I/O unit 30. These include digital inputs and outputs, analog inputs and outputs, infrared inputs and outputs, X-10 ports, and serial ports. The peripheral I/O units have similar types of I/O, but specific inputs and outputs are not shown for clarity.

FIG. 2 is a block diagram representation of an alternative home automation system with a central controller 40. This controller can be built around a personal computer or workstation, or can be a stand-alone controller specifically designed for home automation. In any case, it contains, at a minimum, a central processing unit (CPU) and memory. It may also contain fixed or removable storage media devices. The central controller 40 is connected, by means of a data bus, or its equivalent, through a plurality of standard or custom interfaces to either control each of the subsystems automated within the premises environment or to transmit or receive either data or instructions from within the premises environment. The central controller accesses these subsystems in this case through a multi-serial interface 41, and a network interface 42. In this case, an Ethernet network is used. If the central control system is a personal computer or workstation, the multi-serial and Ethernet interfaces may be devices actually installed in the workstation as adapter cards. Alternatively, they can be independent devices connected through a standard interface such as a universal serial bus (USB). In the case of a dedicated central controller such as might be installed in a basement or wiring closet, they may be connected through some type of proprietary interface.

In this example, multi-serial interface 41 provides connectivity through an RS-232 type serial interface to numerous household systems, such as the HVAC system 43, and the security system 44. If a premises system uses a protocol other than RS-232 or the network protocol, then a protocol converter 45, can be used to convert between the RS-232 protocol and the protocol utilized by the device to be controlled. In this example, protocol converter 45 provides connectivity via X-10 and CE Bus.

The system of FIG. 2 is designed to connect to a network such as Ethernet, by means of the Ethernet network interface 42. Using such an interconnection, a wide variety of applications such as information retrieval and remote home automation control can be achieved. In this particular example, a home PC 46 is shown on the Ethernet. Other Ethernet devices 47, are also shown by way of illustration.

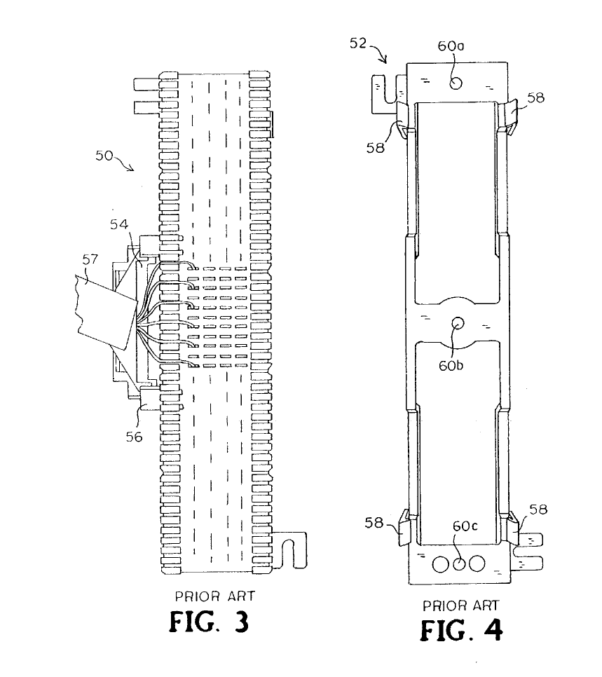

FIGS. 3 and 4 respectively show a prior art 66 block 50 and an 89B holder 52. A standard 25 pair “D” connector 54, 56 connects the block 50 to the cable 57. Four snap-in tabs 58 on the holder 52 hold the block. There are three cylindrical raised “buttons” 60 a, 60 b, 60 c on the holder 52.

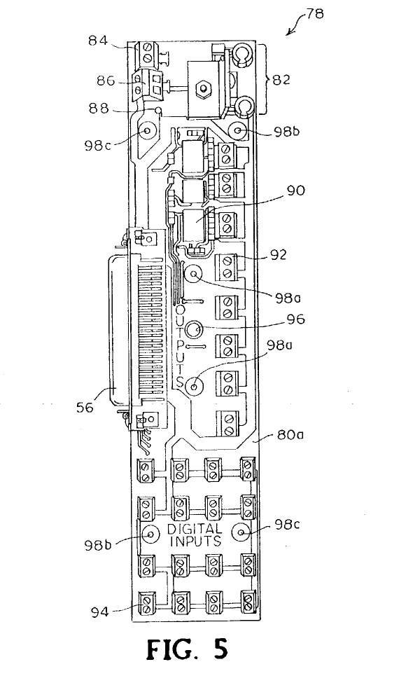

Examples of components embodying the present invention are shown in FIGS. 5-15. A digital I/O board 78 is shown in FIG. 5, comprising a “full-size” PCB 80 a, a 25 pair “D” connector 56, 12V voltage regulator 82, regulated voltage out (+12V) 84, unregulated power out 86, power LED 88, 3 relays 90, 8 digital outputs 92, and 16 digital inputs 94.

The PCB 80 is a size that fits snuggly within the holder 52 and is full size. The PCB 80 has a planimetric shape, or “form factor”, that allows it to be snapped into and held in a conventional punchdown block holder. Nominal dimensions of this full-size PCB 80 a are 2.1-inches wide by 10-inches long. The thickness of the board 80 a is 0.062-inches. Note that soldered connections on the bottom of the board make the board stand up off of an 89B holder 52. The exact dimensions may vary. Note also that a hole 96 is provided in this embodiment of the board 80 a, through which the central button 60 b on the 89B holder may pass to prevent sliding of the I/O board 78. Holes in the PCB 80 a are not required at each end to match with the other 89B buttons 60 a, 60 c because the shown PCB flexes at each end to fit in the holder 52. A thicker PCB, on the order of 0.1-inches, may be used, with additional holes provided if necessary to fit in the holder.

Holes 98 a, 98 b, 98 c are provided as a consistent template to allow mounting of a full-size board to an adapter, described below, or to allow reduced-size boards, also described below, to be mounted on top of the board 78. The position of these holes may vary in general, but the counterpart holes in other components according to the present invention should be positioned likewise. Fasteners, such as screws and spacers as appropriate, may be selected as known by one of ordinary skill in the art. Threaded spacers, not shown, are one means for mounting the components while maintaining space between them.

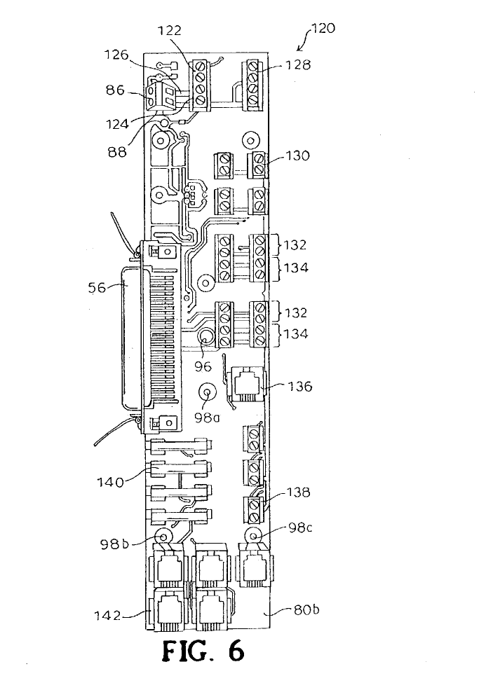

FIG. 6 shows a telephone/infrared (telco/IR) board 120, which provides an interface between a premises automation system and telephone lines. Some of the features of the telco/IR board 120 are a 485 communications port 122, power 124, a transient suppression device 126, audio outputs 128 to 2 speakers, 4 infrared outputs 130, 4 infrared inputs 132 for control of remote control devices, each with corresponding power 134, an RJ11 jack 136 to an X10 module, bi-directional digital connections 138 to Dallas Semiconductor 1-Wire® devices (1-WIRE is a registered trademark of Dallas Semiconductor Corporation), fuses 140, and RJ11 jacks 142 for telephone connections related to premises automation.

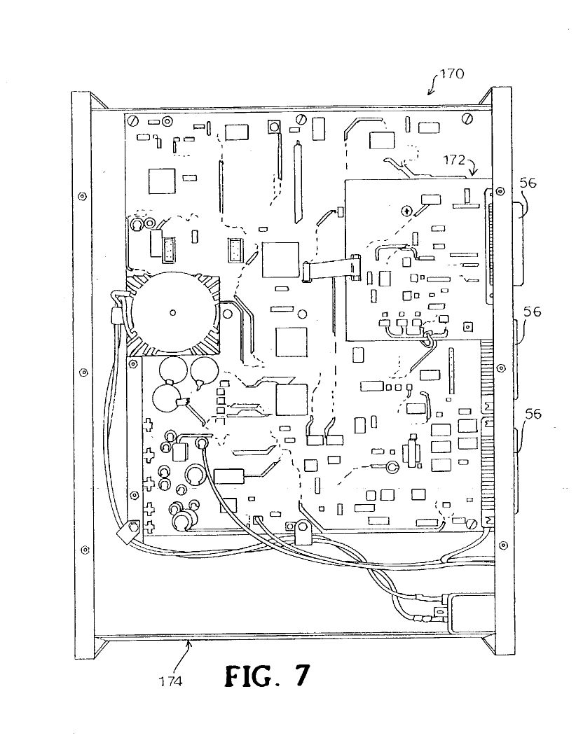

FIG. 7 shows a central unit 170, and an optional I/O board 172. Note that 25 pair “D” connectors 56 may be used on the central unit 170 and an optional I/O board rather than the conventional method of screw terminals or individual connectors. This feature allows the central unit 170 to be designed so as to prevent access to the main circuit board by a user, with an enclosure 174 being provided (cover not shown).

The PCBs of the present invention generally have a connector or cable that goes to the premises automation equipment, and may have multiple terminations on the PCB of different sizes and types for facilitating the connection to the premises wiring. That connection can be directly to the wiring, or it can be via a jumper to a termination means used to terminate the premises wiring.

The side of the circuit board that connects to the premises automation equipment can be ether a permanently connected cable, or it can be a multi-pin connector, such as the existing style of 25 pair “D” connectors conventionally used in telephone systems. The premises automation equipment will generally also have either a hardwired cable or connector. In one embodiment of the invention, both the premises automation equipment and the PCB have connectors to afford maximum flexibility during installation as to the location of the equipment (including premises wiring and other equipment, such as a PBX, network hubs, and Internet access equipment). These connectors allow for rapid change-out of failed equipment for either repair or as a diagnostic tool.

The side of the circuit board that connects to the premises wiring consists of a variety of wire termination means such as screw terminal connections or pin and header connections. Premises automation equipment has a variety of different electrical and physical configurations. For example, a PCB that is snapped into an 89B bracket might have RS232 serial ports that use a standard 9-pin min. “D” subconnector. It may also have two screw terminal connectors for switch contact closure detection. It may additionally have RJ11 jacks for connection to existing equipment such as an X10 transceiver. Although it may incorporate an RJ11 jack, the signals, voltages, and pairing is different from RJ11 's used for telephone systems. It may also have an infrared receiver connection consisting of at least three wires, power, ground, and the received signal. A power pair on the premises automation side may be replicated on many different screw terminal strips for multiple devices that need power.

These examples demonstrate some of the differences of the present invention from the relatively homogeneous world of telephone pairs. In premises automation systems there are many different physical connectors. Wires and pairs from the premises automation side may appear multiple times on the premises wiring connection side. Conventional telephone systems do not have this “one-to-many” pairing.

Further, the PCBs of the present invention may have electronics components on them. There may be LEDs for power indicators, protection devices, and even circuitry such as voltage regulators or interface electronics (such as RS232 to TTL converters). This ability to have electronics on the termination board allows for better upgrade capability. New premises automation systems can provide PCBs that replace existing PCBs for premises wiring connection that can convert older signaling conventions to newer ones.

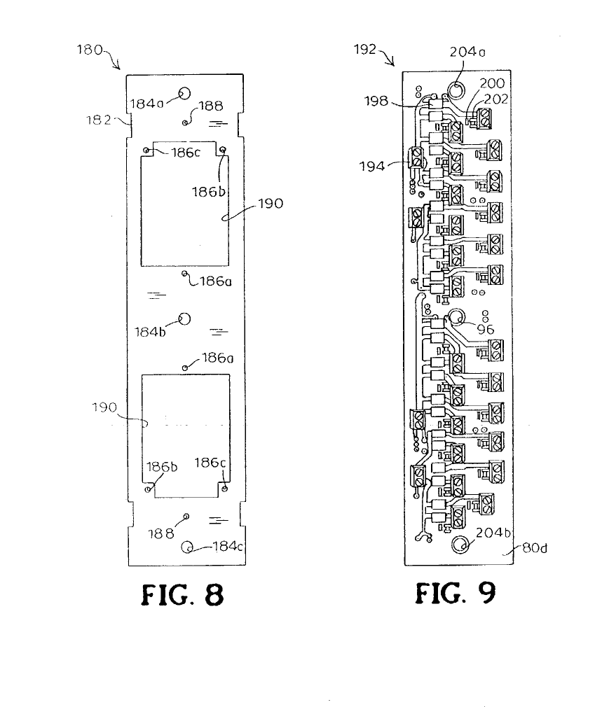

FIG. 8 shows one embodiment of a mechanical adapter 180 according to the present invention. Unless otherwise noted, the term adapter refers to a mechanical adapter of the present invention rather than to an electrical adapter. The form factor of this adapter 180 is made to fit into and be held by the 89b holder, and has outside dimensions of approximately 2.3 inches wide by 10 inches long. The adapter 180 is made of 0.090-inch thick aluminum, although the material may be plastic, other metals, or different materials, as well as a different thickness, as selected by one of ordinary skill in the art. Four slots 182 are provided to accommodate the snap-in tabs 58 of the holder 52. The slots 182 as shown have a depth of 0.1-inch from the outside edge of the adapter. Three holes 184 a, 184 b, 184 c are provided to accept the buttons 60 a, 60 b, 60 c of the 89B holder 52 (FIG. 2) so the adapter will snap into the holder 52.

In all the PCBs, adapters, and enclosures of the present invention that are mounted to a holder, holes may be provided in consistent relative locations on parts that are stacked, conforming to a consistent template and thereby allowing interchangeability of parts and various combinations of components. Two sets of three holes 186 a, 186 b, 186 c are provided to allow fastening through corresponding holes of reduced-size boards, described below. Two holes 188, 186 a are provided on each end to allow fastening of a single chassis enclosure, described below, to the adapter 180. Holes 188, or other holes, may also be used to attach a cover plate.

Voids 190 in the adapter 180 are provided to allow access to circuit connections on the back of boards to be mounted on the adapter 180, or to allow insertion of an enclosure through a void 190. Another embodiment of the adapter 180, not shown, omits the voids 190 and is a solid plate.

FIG. 9 shows a fuse board 192. Four groups of one power input 194 with six power outputs 196 are provided, with a self-resetting fuse 198, LED 200 and resistor 202 inline to each output 196. This permits varying of voltages to the outputs. One example of a use for such a board 192 is as a power supply to multiple cameras. Note that in the embodiment shown there are holes 204 a, 204 b at each end to accept the buttons 60 a, 60 c of an 89B holder 52, but holes 98 a, 98 b, 98 c were omitted in this embodiment; such design variation is available while remaining within the scope of the present invention.

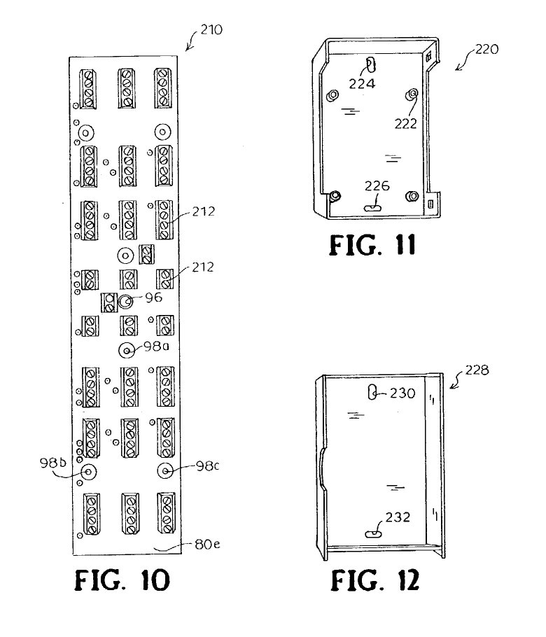

FIG. 10 shows a general purpose interconnect board 210 that allows making connections straight across the terminals 212 as well as altering the connection pattern.

FIG. 11 shows an enclosure bottom 220 for a reduced-size board in accordance with the present invention. Holes 222 for mounting a reduced-size board are provided, as are holes 224, 226 for mounting the enclosure bottom 220 to an adapter 180 of the present invention using holes 188, 186 a, described above (FIG. 8). FIG. 12 shows a top or cover 228 for the enclosure bottom 220, with holes 230, 232 to match the holes 224, 226 in the enclosure bottom 220.

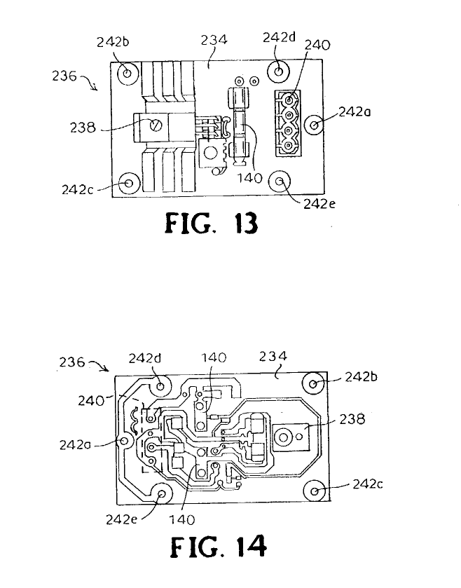

FIGS. 13 and 14 show top and bottom of a reduced-size PCB 234. This PCB 234 is an adjustable voltage regulator board 236 including an adjustable voltage regulator 238, a fuse 140, and pin and header-type connector 240. Alternate connections known to one of ordinary skill in the art may be provided, for example, an RJ45 jack or screw terminals. These boards can be mounted in chassis/enclosures 220,228, in standard single-gang wall outlet boxes, or to the adapter. Once again, the reduced-size boards 234 have holes conforming to a template that allows mounting to an adapter 180 or a full-size board.

The three holes 242 a, 242 b, 242 c coincide with the similar holes 186 a, 186 b, 186 c of the adapter 180 (FIG. 8) to allow mounting of the reduced size board 234, and in addition, also allow mounting to full-size PCBs in counterpart holes 98 a, 98 b, 98 c. The five holes 242 a, 242 b, 242 c, 242 d, 242 e in the board 234 also coincide with the holes 222, 224 in the single chassis enclosure 220 (FIG. 11) for mounting therein. The single chassis enclosure 220 may be widened to house multiple reduced-size boards. A wide variety of board types may be constructed in accordance with the present invention. For example, one of ordinary skill in the art may design fuse boards, fixed voltage regulators, relay boards (single- and double-pole, single- and double-throw), and optical isolation boards, among other circuits. It may readily be seen that relays of various contact configurations and current carrying capacities may be provided on boards and mounting assemblies in accordance with the present invention.

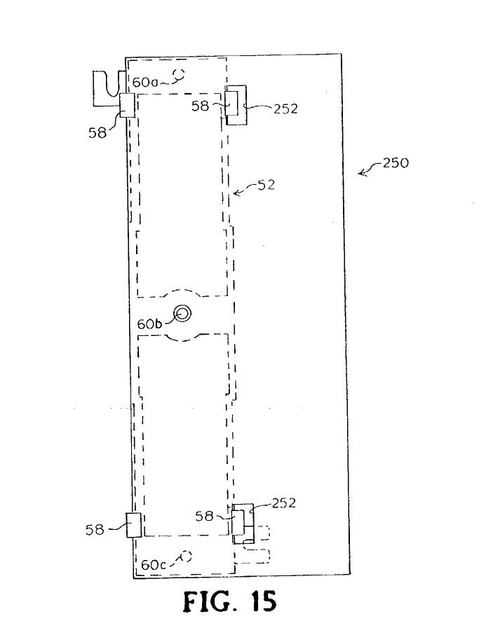

FIG. 15 shows a plan view of one embodiment of an over-sized board 250, including holes 252 in the board for snap-in tabs 58 of a holder 52. Alternatively, over-sized boards may snap into more than one holder 52 at a time, or may have different locations of holes for the snap-in tabs 58.

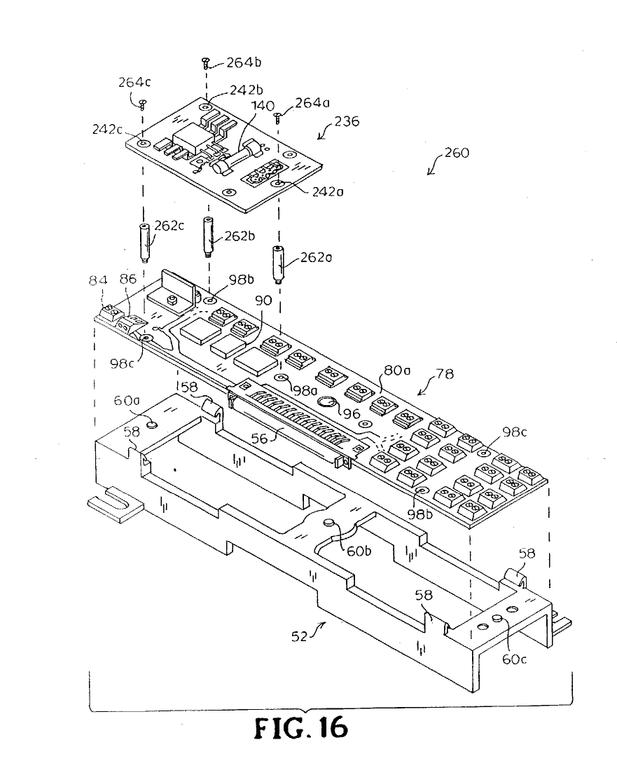

A mounting assembly 260 is shown in FIG. 16. The assembly comprises an 89B punchdown block holder 52, a full-size PCB 78, and a reduced-size PCB 236. Threaded spacers 262 a, 262 b, 262 c and screws 264 a, 264 b, 264 c connect through respective holes 242 a, 242 b, 242 c in the reduced-size PCB 236. The holes 242 a, 242 b, 242 c are aligned with the holes 98 a, 98 b, 98 c in the full-size PCB 78, allowing the threaded spacers 262 a, 262 b, 262 c to fasten the reduced-size PCB 236 to the full-size PCB 78. The full-size PCB 78 snaps between the tabs 58 and into the holder 52. A hole 96 in the full-size PCB 78 fits over a button 60 b on the holder 52. As shown, the PCB 78 flexes so that additional holes are not needed to receive the other buttons 60 a, 60 c, but additional holes may be required depending on the rigidity of the PCB.

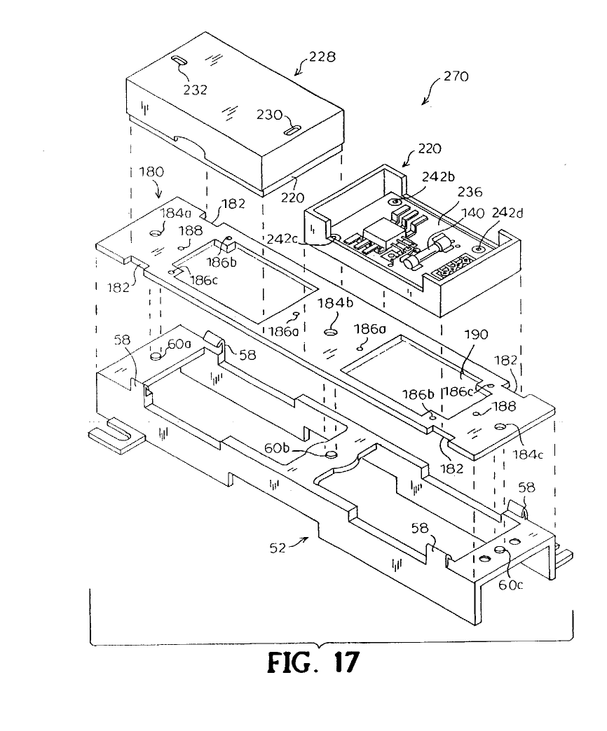

Another mounting assembly 270 is shown in FIG. 17. Two chassis 220, one shown with a cover 228, are mounted to an adapter 180. The adapter 180 snaps into the holder 52 with the recessed areas 182 receiving the tabs 58. Holes in the adapter 184 a, 184 b, 184 c receive the buttons 60 a, 60 b, 60 c. Fasteners are not shown in FIG. 17. Each chassis 220 is fastened to the adapter 180 with screws through chassis holes 224, 226 and adapter holes 188, 186 a. A reduced-size PCB 236 is mounted to the chassis 220 with screws through PCB holes 242b, 242c, 242d, 242e (242e not visible) and chassis holes 222.

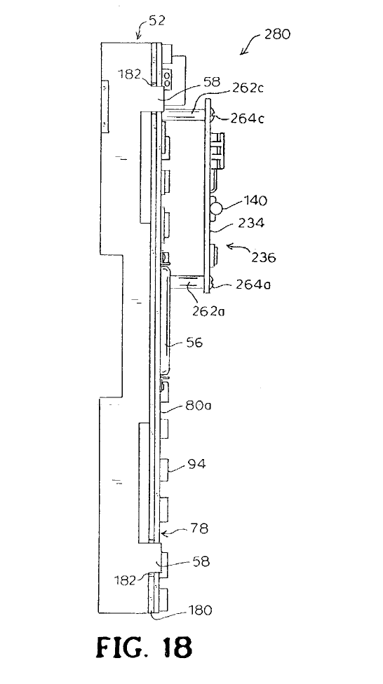

A mounting assembly 280 is shown in an assembled view in FIG. 18. In this embodiment a holder 52 holds an adapter 180, to which a full-size PCB is mounted. A reduced-size PCB 236 is mounted to the full-size PCB 78 using threaded spacers 262 and screws 264.

The present invention enables the connections to the premises automation equipment and the premises wiring to share a common spatial form factor, that of the 66 and 89B bracket or other chosen apparatus. This also allows existing commercially available wall-mounted cabinets, which are pre-punched to hold the brackets to be used and have protective covers. These cabinets are economical due to the high volumes in which they are manufactured.

The three embodiments of mounting assemblies 260, 270, 280 described above are but a few of the many combinations of components and arrangements that are available according to the present invention. It should be noted that various modifications to the design of the components described herein may be made without deviating from the scope of the present invention.

1. A mount for premises automation system components using a punchdown block holder, the punchdown block holder having a top surface and opposing tabs for biasing a substantially planar object against the top surface, the mount comprising a first printed circuit board adapted to be reciprocally received by the opposing tabs.

2. A mount as recited in claim 1, wherein the first printed circuit board has a form factor as defined by the opposing tabs and the top surface of the punchdown block holder.

3. A mount as recited in claim 1, wherein the first printed circuit board has a form factor larger than the planimetric shape defined by the opposing tabs and the top surface of the punchdown block holder, and has voids through which the printed circuit board is reciprocally received by the opposing tabs.

4. A mount as recited in claim 1, wherein the first printed circuit board has a plurality of holes therethrough and further comprising a second printed circuit board having holes therethrough coaxial with the holes in the first printed circuit board, and wherein the second printed circuit board is mounted to the first printed circuit board with fasteners through the respective holes.

5. A mount as recited in claim 4, wherein the form factor of the second printed circuit board is substantially the same as the first printed circuit board.

6. A mount as recited in claim 4, wherein the form factor of the second printed circuit board is smaller than that of the first printed circuit board.

7. A mount for premises automation system components using a punchdown block holder, the punchdown block holder having a top surface and opposing tabs for biasing a substantially planar object against the top surface, the mount comprising a substantially planar adapter adapted to be reciprocally received by the opposing tabs.

8. A mount as recited in claim 7, wherein the adapter has a form factor as defined by the opposing tabs and the top surface of the punchdown block holder.

9. A mount as recited in claim 7, wherein the adapter has a form factor larger than the planimetric shape defined by the opposing tabs and the top surface of the punchdown block holder, and has voids through which the adapter is reciprocally received by the opposing tabs.

10. A mount as recited in claim 7, wherein the adapter has a plurality of holes therethrough and further comprising a printed circuit board having holes therethrough coaxial with the holes in the adapter, and wherein the printed circuit board is mounted to the adapter with fasteners through the respective holes.

11. A mount as recited in claim 10, wherein the form factor of the printed circuit board is substantially the same as the adapter.

12. A mount as recited in claim 10 wherein the form factor of the printed circuit board is smaller than that of adapter.

13. A mount as recited in claim 10, wherein the form factor of the printed circuit board is larger than the form factor of the adapter.

14. A mounting assembly for premises automation system components, the assembly comprising:
a punchdown block holder having a top surface and opposing tabs for biasing a substantially planar object against the top surface; and
a first printed circuit board adapted to be reciprocally received by the opposing tabs.

15. A mounting assembly as recited in claim 14, wherein the first printed circuit board has a form factor as defined by the opposing tabs and the top surface of the punchdown block holder.

16. A mounting assembly as recited in claim 14, wherein the first printed circuit board has a form factor larger than the planimetric shape defined by the opposing tabs and the top surface of the punchdown block holder, and has voids through which the printed circuit board is reciprocally received by the opposing tabs.

17. A mounting assembly as recited in claim 14, wherein the first printed circuit board has a plurality of holes therethrough and further comprising a second printed circuit board having holes therethrough coaxial with the holes in the first printed circuit board, and wherein the second printed circuit board is mounted to the first printed circuit board with fasteners through the respective holes.

18. A mounting assembly as recited in claim 17, wherein the form factor of the second printed circuit board is substantially the same as the first printed circuit board.

19. A mounting assembly as recited in claim 17, wherein the form factor of the second printed circuit board is smaller than that of the first printed circuit board.

20. A mounting assembly for premises automation system components, the assembly comprising:
a punchdown block holder having a top surface and opposing tabs for biasing a substantially planar object against the top surface; and
a substantially planar adapter adapted to be reciprocally received by the opposing tabs.

21. A mounting assembly as recited in claim 20, wherein the adapter has a plurality of holes therethrough and further comprising a printed circuit board having holes therethrough coaxial with the holes in the adapter, and wherein the printed circuit board is mounted to the adapter with fasteners through the respective holes.

22. A mounting assembly as recited in claim 21, wherein the form factor of the printed circuit board is substantially the same as the adapter.

23. A mounting assembly as recited in claim 21, wherein the form factor of the printed circuit board is smaller than that of adapter.

24. A mounting assembly as recited in claim 21, wherein the form factor of the printed circuit board is larger than the form factor of the adapter.

25. A mounting assembly as recited in claim 20, wherein the substantially planar adapter has a plurality of holes therethrough and further comprising:
an enclosure comprising a top mounted to a bottom, the bottom having a form factor smaller that of the adapter, having a first hole therethrough coaxial with a hole in the adapter, the bottom mounted to the adapter with fasteners through the respective holes, and the bottom having a second hole therethrough; and
a printed circuit board having a form factor smaller than the interior of the bottom of the enclosure, having a hole therethrough coaxial with the second hole in the enclosure, and mounted to the interior bottom enclosure with fasteners through the respective holes.

26. A premises automation system comprising:
an independently mounted central unit;
a device controlled by the central unit;
a punchdown block holder having a top surface and opposing tabs for biasing a substantially planar object against the top surface; and
a printed circuit board adapted to be reciprocally received by the opposing tabs, and electrically interposed between central unit and the device.

27. A premises automation system comprising:
an independently mounted central unit;
a device controlled by the central unit;
a punchdown block holder having a top surface and opposing tabs for biasing a substantially planar object against the top surface;
a substantially planar adapter adapted to be reciprocally received by the opposing tabs, the adapter having holes therethrough;
a printed circuit board having holes therethrough coaxial with holes in the adapter, mounted to the adapter with fasteners, and electrically interposed between central unit and the device.

28. A method of mounting premises automation system components, the steps comprising:
providing a punchdown block holder having a top surface and opposing tabs for biasing a substantially planar object against the top surface;
providing a printed circuit board adapted to be reciprocally received by the opposing tabs; and
inserting the printed circuit board between the opposing tabs.

29. A method of mounting premises automation system components, the steps comprising:
providing a punchdown block holder having a top surface and opposing tabs for biasing a substantially planar object against the top surface;
providing a substantially planar adapter adapted to be reciprocally received by the opposing tabs;
inserting the adapter between the opposing tabs, the adapter having holes therethrough;
providing a printed circuit board having holes therethrough coaxial with holes in the adapter; and
mounting the printed circuit board to the adapter with fasteners through the respective holes.

30. A mount for premises automation system components using a standard single-gang wall outlet box, the outlet box having an interior surface formed by a rear and four sides with at least two holes through the rear, the mount comprising a printed circuit board having a form factor smaller then the interior rear of the outlet box, and two holes coaxial with the two holes through the rear of the outlet box, wherein the printed circuit board is mounted to the interior rear of the outlet box with fasteners through the coaxial holes.
